(19) United States
(12) Patent Application Publication
(10) Pub. No.: US 2026/0282559 A1
(43) Pub. Date: Sep. 17, 2026

(54) DIODE STRUCTURES OF STACKED TRANSISTORS AND METHODS OF MANUFACTURING THE SAME

(71) Applicant: Samsung Electronics Co., Ltd., Suwon-si (KR)

(72) Inventors: Beomjin Park, Halfmoon, NY (US); Gwangsik Kim, Clifton Park, NY (US); Jongmin Shin, Niskayuna, NY (US); Young Gook Park, Wynantskill, NY (US); Junmo Park, Clifton Park, NY (US); Kang-ill Seo, Springfield, VA (US)

(21) Appl. No.: 19/297,571

(22) Filed: Aug. 12, 2025

Related U.S. Application Data
(60) Provisional application No. 63/770,490, filed on Mar. 12, 2025.

(51) Int. Cl. H10D 89/60; H10D 84/01; H10D 84/85

(52) U.S. Cl. CPC H10D 89/611; H10D 84/017; H10D 84/0186; H10D 84/851; H10D 84/856

(57) ABSTRACT

A three-dimensional (3D) transistor structure includes a first stacked transistor structure including a first lower source/drain (S/D) region and a first upper S/D region stacked thereon with an insulating layer therebetween. The first lower S/D region has a first conductivity type, and the first upper S/D region has a second conductivity type that is opposite to the first conductivity type. A first contact is connected to the first upper S/D region, and a second contact is connected to the first lower S/D region. A shared contact connects the first upper S/D region to the first lower S/D region. Related devices and fabrication methods are also discussed.

### CLAIM OF PRIORITY

This application claims priority from U.S. Provisional Patent Application Ser. No. 63/770,490 entitled “Diode Structures of Stacked Transistors and Methods of Manufacturing the Same,” filed Mar. 12, 2025, with the United States Patent and Trademark Office, the disclosure of which is incorporated by reference herein in its entirety.

### FIELD

The present disclosure relates to circuit devices and methods of forming the same.

### BACKGROUND

The size of transistors in integrated circuit devices has continued to decrease in order to maintain downscaling of logic elements. Technology to increase transistor density and concentrate more transistors within the same area and improve the performance of transistors continues to be developed. For example, as transistor density is increased, a gate extension that does not land on or make connection to a gate contact may be a factor contributing to parasitic capacitance. In fin field effect transistors (FinFETs), it may be challenging to reduce gate extension without affecting the channel width. However, in Gate-All-Around (GAA) devices, where channels are stacked vertically, it may be possible to reduce or minimize parasitic capacitance without substantially reducing the channel width. As such, three-dimensional (3D) device structures and related fabrication processes are under consideration.

One type of 3D device structure is a stacked transistor. Integrated circuit devices may utilize stacked transistors to increase density and improve performance. In some instances, the stacked transistors may be complementary to each other (e.g., complementary metal-oxide-semiconductor (CMOS) transistors). For example, a complementary-FET (CFET) layout may include multiple vertically stacked pairs of gate-all-around field effect transistors (GAAFETs), with P-type GAAFETs on one-level, N-type GAAFETs on another level (i.e., above or below), and shared gates, where each shared gate extends between and wraps around the channel patterns of the stacked pair of N-type and P-type GAAFETs. In such structures, the source/drain regions of the lower GAAFET are electrically isolated from the source/drain regions of the upper GAAFET by dielectric layers. The gates, channel patterns, and isolation structures may be otherwise be similar in dimensions between the upper and lower devices of the stacked transistors.

### SUMMARY

Some embodiments of the present disclosure may implement a diode structure (e.g., a bipolar junction transistor or P-N junction diode) in a stacked transistor structure by providing a shared contact (e.g., a metal or semiconductor contact) that extends between one or more opposite conductivity type source/drain regions of the stacked transistor structure. Elements of a bipolar junction transistor or a P-N junction diode may thereby be formed concurrently with elements (e.g., channel layers and/or source/drain regions) of stacked field effect transistors using many of the same fabrication processes, even when the underlying substrate is removed or thinned to provide a backside power distribution network structure.

According to embodiments, a three-dimensional (3D) transistor structure comprises a first stacked transistor structure including a first lower source/drain (S/D) region and a first upper S/D region stacked thereon with an insulating layer therebetween, where the first lower S/D region has a first conductivity type, and the first upper S/D region has a second conductivity type that is opposite to the first conductivity type. The structure further comprises a first contact connected to the first upper S/D region, a second contact connected to the first lower S/D region, and a shared contact connecting the first upper S/D region to the first lower S/D region.

In some embodiments, the shared contact penetrates the first upper S/D region to contact the first lower S/D region.

In some embodiments, the shared contact comprises a metal, and the first and second contacts comprise anode and cathode contacts of a semiconductor-metal-semiconductor diode.

In some embodiments, the shared contact is free of a silicide of the metal.

In some embodiments, the shared contact comprises a semiconductor, and the first and second contacts comprise anode and cathode contacts of a PIN diode.

In some embodiments, the semiconductor comprises undoped silicon.

In some embodiments, the semiconductor comprises doped silicon.

In some embodiments, the shared contact is a first shared contact, and the structure further comprises a second stacked transistor structure comprising a second upper S/D region stacked on the first lower S/D region, where the second upper S/D region has the second conductivity type, a second shared contact connecting the second upper S/D region to the first lower S/D region, and a third contact connected to the second upper S/D region, where the first, second, and third contacts comprise emitter, base, and collector contacts, respectively, of a bipolar junction transistor.

In some embodiments, the structure further comprises a substrate having the first lower S/D region thereon between the substrate and the first upper S/D region, where the second terminal penetrates the substrate to contact the first lower S/D region.

In some embodiments, the substrate comprises a bulk semiconductor substrate or an insulating substrate.

In some embodiments, an upper surface of the shared contact is substantially coplanar with an upper surface of the first contact and/or the second contact.

In some embodiments, the first stacked transistor structure further comprises a plurality of upper and lower channel regions and gates alternately stacked.

According to some embodiments, a three-dimensional (3D) transistor structure comprises at least one lower source/drain (S/D) region of a first conductivity type; upper S/D regions of a second conductivity type opposite to the first conductivity type stacked on the at least one lower S/D region, the upper S/D regions comprising a first upper S/D region and a second upper S/D region; a first shared contact connecting the first upper S/D region to the at least one lower S/D region; a second shared contact connecting the second upper S/D region to the at least one lower S/D region; a first collector/emitter contact connected to the first upper S/D region; a second collector/emitter contact connected to the second upper S/D region; and a base contact connected to the at least one lower S/D region.

In some embodiments, the first and second shared contacts penetrate the first upper S/D region and the second upper S/D region, respectively, to contact the at least one lower S/D region.

In some embodiments, the shared contact comprises a metal.

In some embodiments, the shared contact comprises a doped or undoped semiconductor.

In some embodiments, the structure further comprises a substrate having the at least one lower S/D region thereon between the substrate and the upper S/D regions, where the base contact penetrates the substrate to contact the at least one lower S/D region.

According to some embodiments, a method of fabricating a three-dimensional (3D) transistor structure comprises forming preliminary transistor structures on a substrate; removing a portion of the preliminary transistor structures to form upper transistor structures that are spaced apart from one another on one or more lower transistor structures; forming one or more lower source/drain (S/D) regions of the at least one lower transistor structure, the one or more lower S/D regions having a first conductivity type; forming upper S/D regions of the upper transistor structures on the one or more lower S/D regions with an interlayer insulating layer therebetween, the upper S/D regions having a second conductivity type that is opposite the first conductivity type; and forming shared contacts that connect the upper S/D regions to the one or more lower S/D regions.

In some embodiments, forming the shared contacts comprises forming contact openings that penetrate the upper S/D regions and the interlayer insulating layer; and forming the shared contacts in the contact openings.

In some embodiments, forming the shared contacts comprises forming a metal in the contact openings.

In some embodiments, forming the shared contacts comprises forming a semiconductor in the contact openings.

In some embodiments, the semiconductor comprises undoped silicon.

In some embodiments, the semiconductor comprises doped silicon.

In some embodiments, forming the shared contacts further comprises implanting dopants into the semiconductor in the contact openings.

In some embodiments, the method further comprises forming first contacts on the upper S/D regions; and forming a second contact on the one or more lower S/D regions.

In some embodiments, forming the first contacts and the second contacts comprises forming an insulating layer on the upper S/D regions and the one or more lower S/D regions; forming openings in the insulating layer that expose the upper S/D regions and the one or more lower S/D regions; and forming the first contacts and the second contact in the openings.

In some embodiments, upper surfaces of the shared contacts are substantially coplanar with upper surfaces of the first contact and the second contact.

In some embodiments, forming the second contact comprises forming an opening in the substrate that exposes the one or more lower S/D regions; and forming the second contact in the opening.

In some embodiments, the substrate is a semiconductor substrate, and the method further comprises removing the semiconductor substrate after forming the first and second contacts; and forming an insulating substrate on the one or more lower S/D regions after removing the semiconductor substrate.

In some embodiments, the one or more lower S/D regions comprises a unitary epitaxial region or a unitary implanted region, and the upper S/D regions comprise respective epitaxial regions or implanted regions.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the present disclosure, and be protected by the accompanying claims.

### BRIEF DESCRIPTION OF THE DRAWINGS

FIGS. 1A, 1B, 1C, and 1D are schematic cross-sectional views illustrating example 3D transistor structures including integrated diode structures with frontside contacts on bulk substrates according to some embodiments of the present disclosure.

FIG. 2 is a schematic cross-sectional view illustrating an example 3D transistor structure including integrated diode structures with frontside contacts and free of the bulk substrate according to some embodiments of the present disclosure.

FIG. 3 is a schematic cross-sectional view illustrating an example 3D transistor structure including integrated diode structures with frontside contacts and a backside contact through the bulk substrate according to some embodiments of the present disclosure.

FIG. 4 is a schematic cross-sectional view illustrating an example 3D transistor structure including integrated diode structures with frontside contacts and a backside contact through an insulating substrate according to some embodiments of the present disclosure.

FIGS. 5A, 5B, 5C, 5D, 5E, 5F, 5G, 5H, 5I, 5J1, and 5J2 are schematic cross-sectional views illustrating methods of fabricating 3D transistor structures including integrated diode structures according to some embodiments of the present disclosure.

FIG. 6 is a flowchart illustrating methods of fabricating a 3D transistor structure including integrated diode structures according to some embodiments of the present disclosure.

FIG. 7 is a schematic cross-sectional view illustrating an example 3D transistor structure according to some embodiments of the present disclosure.

### DETAILED DESCRIPTION OF EMBODIMENTS

Example embodiments are described herein with reference to the accompanying drawings, which may include cross-section illustrations that are schematic illustrations of idealized embodiments (and intermediate structures). The sizes and relative sizes of layers and regions may be exaggerated for clarity. Additionally, variations from the shapes of the illustrations as a result, for example, of manufacturing techniques and/or tolerances, are to be expected. The same reference numerals may be used to refer to the same or similar elements in various embodiments, where reference numerals followed by a dash (-1, -2, etc.) or one or more prime symbols (′) may refer to specific instances or variations of the same or similar elements.

In embodiments described herein, a stacked transistor structure may include a first transistor and a second transistor. The first transistor may be a first type of transistor (e.g., a n-type metal-oxide-semiconductor (NMOS) transistor) and the second transistor may be a second type of transistor (e.g., a p-type metal-oxide-semiconductor (PMOS) transistor). The first and second types of transistors may be complementary to each other (e.g., CMOS transistors), and in some embodiments the stacked transistor structure may be or may include a stack of CMOS transistors. The first and second transistors may be stacked in any order (e.g., with the first transistor on top of the second transistor, or the second transistor on top of the first transistor), resulting in a stack comprising a top device (also referred to herein as an upper device or upper transistor, relative to an underlying substrate) and a bottom device (also referred to herein as a lower device or lower transistor, relative to the underlying substrate).

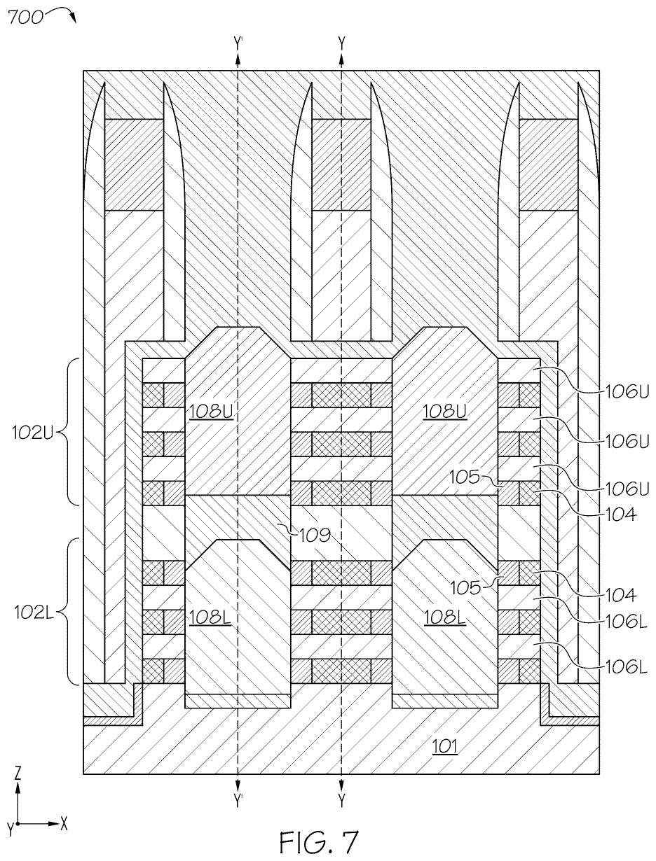

FIG. 7 is a schematic cross-sectional view illustrating an example 3D transistor structure 700 according to some embodiments of the present disclosure. As shown in FIG. 7, an integrated circuit device includes a stacked transistor structure 102 including upper and lower transistors 102L, 102U vertically stacked on a substrate 101. The lower transistor 102L includes at least one lower channel pattern 106L between conductive gates 104. The upper transistor 102U includes at least one upper channel pattern 106U between gates 104. In the example of FIG. 7, multiple upper channel patterns 106U are stacked on multiple lower channel patterns 106L, with the gates 104 alternatingly stacked between the channel patterns 106L, 106U (collectively 106; also referred to herein as channel regions 106), but embodiments of the present disclosure may include fewer or more channel patterns than shown. The channel patterns or regions 106 may be provided by semiconductor materials, such as silicon (Si). The stacked transistor structure 102 may further include inner spacers 105 (e.g., formed of insulating or dielectric materials, for example, SiOCN or other low-k dielectric material), and additional semiconductor (e.g., Si) and insulator (e.g., SiN, SiO) layers stacked on the channel patterns 106.

Lower source/drain regions 108L of the lower transistor 102L are provided on opposing sides (also referred to herein as opposing ends) of the lower channel patterns 106L, and upper source/drain regions 108U of the upper transistor 102U are provided on opposing sides or ends of the second channel patterns 106U. The lower source/drain regions 108L may be electrically separated from the upper source/drain regions 108U by one or more interlayer insulating layers 109. Gate insulating spacers 105 (e.g., silicon nitride patterns; also referred to as inner spacers) may be provided on opposing sides of the gate patterns 104 to electrically insulate the gate patterns 104 from the source/drain regions 108L, 108U (collectively, 108). In some embodiments, the lower source/drain regions 108L may include a same material or material composition as the lower channel patterns 106L and/or the substrate 101. For example, the lower channel patterns 106L and the lower source/drain regions 108L may be implemented as silicon layers. In some embodiments, the upper source/drain regions 108U may include a different material or material composition than the lower source/drain regions 108L. For example, the upper source/drain regions 108U may be implemented as silicon germanium (SiGe) layers.

In the example of FIG. 7, the lower transistors 102L and upper transistors 102U have complementary conductivity types, e.g., to provide a CMOS device. In particular, the lower transistors 102L may have a first conductivity type (e.g., n-type), while the upper transistors 102U may have a second conductivity type (e.g., p-type) that is opposite to the first conductivity type, or vice versa. That is, stacked transistor structures 102 according to embodiments of the present disclosure are not limited to particular orientations of transistors having the different conductivity types. Moreover, the lower transistors 102L and upper transistors 102U may have the same conductivity type (e.g., both the lower transistors 102L and upper transistors 102U may be n-type, or both the lower transistors 102L and upper transistors 102U may be p-type) in some embodiments. Also, while illustrated with reference to lower transistors 102L and upper transistors 102U, it will be understood that stacked transistor structures 102 according to embodiments of the present disclosure are not limited to two-transistor arrangement, and may include additional transistors (e.g., third transistors, fourth transistors, etc.) that are vertically stacked on the substrate 101.

That is, each of the lower transistors 102L and upper transistors 102U may include a transistor structure having one or more channel regions 106 (e.g., nanosheet channel regions) extending between source/drain regions 108. Gates 104, channels 106, source/drain regions 108, and inner spacers 105 of the upper and lower devices 102U and 102L may likewise be referred to by the terms “upper” and “lower” (e.g., upper/lower gates, upper/lower channels, upper/lower source/drain regions, and upper/lower inner spacers). Example stacked transistor structures include, but are not limited to, a 3D-stacked field-effect transistor (3DSFET) in a CMOS configuration, a fin transistor, a multibridge-channel field-effect transistor (MBCFET™) in a CMOS configuration, and a MBCFET™ that does not include a bulk silicon substrate (e.g., a bulkless MBCFET) and includes bounded shallow trench isolation (STI) regions.

In some embodiments, a bulkless MBCFET may include a backside power distribution network structure (BSPDN), in which a power rail may be formed on the backside of the semiconductor device rather than on the front side. As such, the power rail may be on a side of the semiconductor structure (e.g., a side of a substrate of the semiconductor device) that is opposite from the active components (e.g., the stacked transistor, such as the MBCFET) of the semiconductor device. Moreover, conductive structures for data signals may be on the frontside of the semiconductor device, and thus the BSPDN and the conductive structures for the data signals may be on opposite sides of the semiconductor device. BSPDN structures may improve power rail effectiveness, voltage drop (i.e., IR drop), high power delivery performance, and further scaling of standard cell height.

Some embodiments of the present disclosure may arise from realization that electrical, performance, and/or operational characteristics of integrated circuit devices including stacked transistor structures may be improved, for example, for ease of implementation of backside power delivery networks (BSPDNs). In particular, an integrated circuit device (e.g., a single chip) may include stacked field-effect transistors (FETs) as well as diode structures, such as a bipolar junction transistor (BJT) and/or a P-N junction diode. For example, a temperature sensing element or an electrostatic discharging element may include a BJT and/or a P-N junction diode. The diode structures may be integrated with the stacked transistor structures in some embodiments. For example, the diode structure includes at least two regions having opposite conductivity types, which can be formed in a substrate having a sufficient thickness to arrange the opposite conductivity type regions in a thickness direction of the substrate. However, when implementing BSPDNs with integrated circuit devices including stacked transistor structures (such as 3DSFETs), a substantial portion of the substrate may be thinned, such that the remaining portion of the substrate may not be thick enough to form a BJT and/or a P-N junction diode therein. As such, it may be more difficult to integrate PNP BJT structures and/or P-N diode structures with BSPDNs in stacked transistor structures (e.g., in comparison to bulk silicon).

Embodiments of the present disclosure include three-dimensional (3D) transistor structures, which may include some features of stacked FET structures (e.g., alternately stacked channels and gates) but may or may not be operable as a field effect transistor. As an example, the 3D transistor structures described herein may incorporate a bipolar junction transistor structure and/or diode structure in which the top and bottom epitaxial structures or layers (such as stacked source/drain regions) have opposite polarities (i.e., opposite conductivity types) and contact each other to define respective junction regions. That is, elements of a P-N junction diode (e.g., an anode region and a cathode region) and/or elements of a BJT (e.g., an emitter, a collector and a base) may be formed on (rather than in) a substrate, such that BJTs and/or P-N junction diodes can be formed in an integrated circuit device even when the substrate is thinned to include a BSPDN. Further, elements of BJTs and/or P-N junction diodes may be formed concurrently with elements (e.g., channel layers and/or source/drain regions) of stacked FETs, using some of the same fabrication processes. Therefore, elements of a BJT and/or a P-N junction diode may be formed without significantly increasing a number of fabrication processes.

Some embodiments of the present disclosure implement a diode structure in a stacked transistor structure by providing a shared contact (e.g., a “connecting” metal or semiconductor contact plug) between one or more opposite conductivity type source/drain regions of a stacked transistor structure. As an example, the 3D transistor structure may include transistor structures having lower and upper source/drain (S/D) regions of opposite conductivity types (e.g., p-type and n-type conductivity) in a stacked (e.g., vertically overlapping) configuration. The stacked lower and upper source/drain (S/D) regions may be connected to each other by respective shared contacts. This structure may differ from the structure of typical 3DSFET transistors, in which the upper and lower S/D regions of a stacked transistor structure are electrically isolated.

In some embodiments, the shared contact may be metal, such that the upper S/D region, the shared metal contact, and the lower S/D region provide a 3D transistor structure that functions as a semiconductor-metal-semiconductor (SMS) diode. The SMS diode may include a p-type region, an n-type region, and a metal region therebetween and forming a Schottky barrier at the metal-semiconductor interfaces. In an energy band diagram of the SMS diode, the conduction band is closer to the fermi level in the n-type region due to excess free electrons in the n-type region, and the conduction band is further from the fermi level in the p-type region due to excess holes (or lack of excess electrons) in the p-type region.

In some embodiments, the shared contact may be a semiconductor material, such as a doped or undoped (i.e., not intentionally doped, also referred to as intrinsic) semiconductor layer, such that the upper S/D region, the shared semiconductor contact, and the lower S/D region provide a 3D transistor structure that functions as a PIN diode. A PIN diode typically includes an undoped intrinsic semiconductor layer sandwiched between a P-type and an N-type semiconductor region. The intrinsic semiconductor layer provides a higher-resistance region between the p-type an n-type regions.

In some embodiments, the 3D transistor structure may include adjacent first and second transistor structures that include first and second upper source/drain (S/D) regions, respectively, which are electrically connected one or more lower S/D regions by respective shared (metal or semiconductor) contacts. A collector contact and an emitter contact may be provided on the first and second upper S/D regions and a base contact may be provided on the lower S/D region(s) to therefore provide a 3D transistor structure that functions as a bipolar junction transistor.

More generally, as described in greater detail below, upper and lower source/drain regions of opposite conductivity types in a 3D transistor structure may be connected by a shared (metal or semiconductor) contact to form or otherwise implement a diode structure. Additional contacts (e.g., anode and cathode contacts, or emitter, base, and collector contacts) may be formed to provide diodes or bipolar junction transistors. That is, stacked n-type and p-type epitaxial regions of a 3DSFET structure may be connected by a shared contact to form a SMS diode (where the shared contact includes a metal), a PIN diode (where the shared contact includes a semiconductor, such as undoped or doped polysilicon), or a BJT (which may include the SMS or PIN diodes).

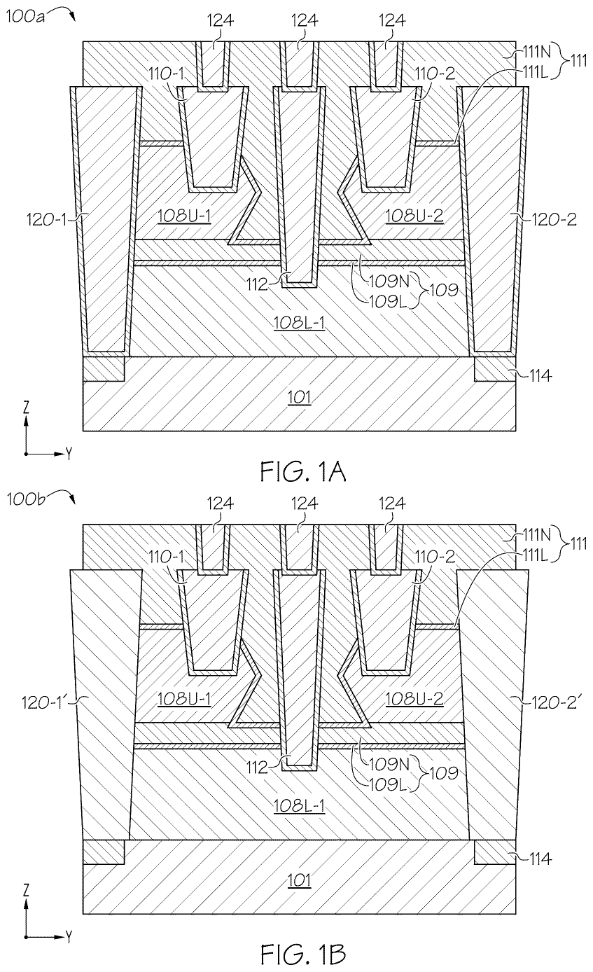

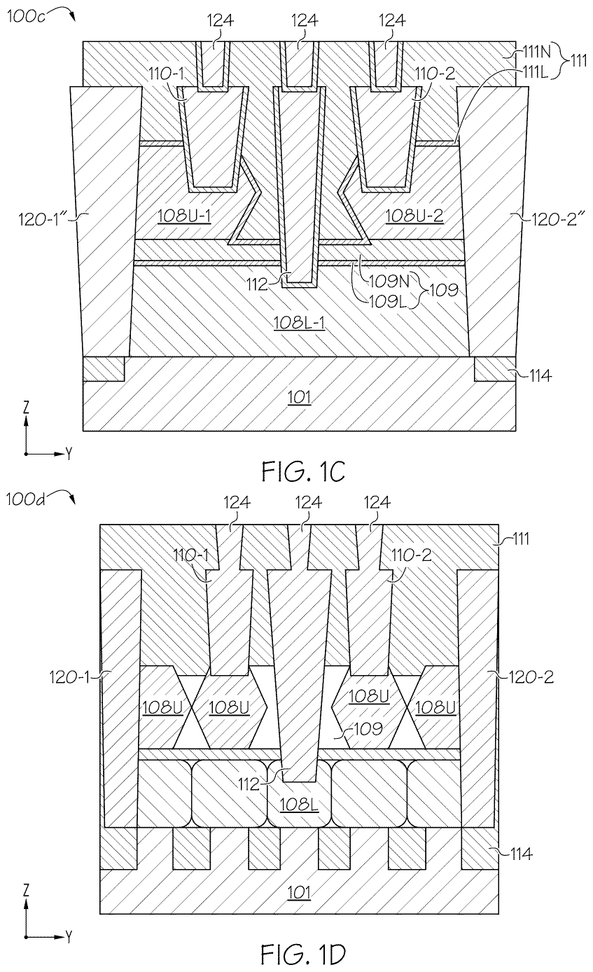

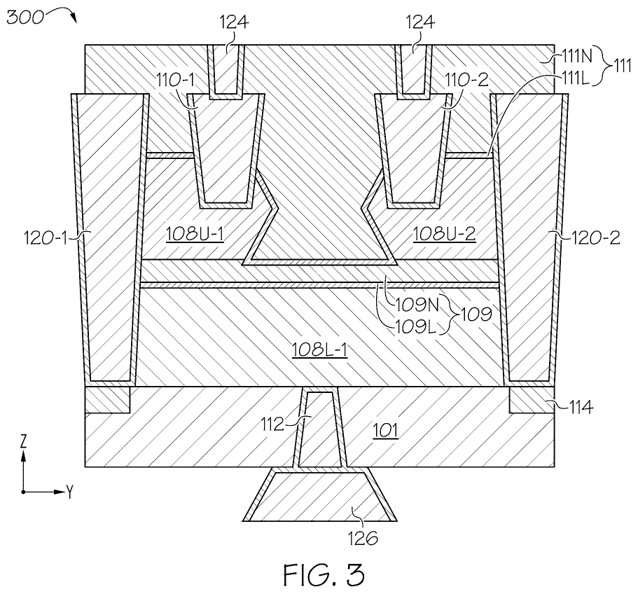

FIGS. 1A, 1B, 1C, and 1D are schematic cross-sectional views illustrating example 3D transistor structures 100a, 100b, 100c, and 100d, respectively, including integrated diode structures with frontside contacts on bulk substrates according to some embodiments of the present disclosure. Referring to FIGS. 1A-1D, 3D transistor structures 100a-100d according to some embodiments of the present disclosure include a first stacked transistor structure 102-1 including a first lower S/D region 108L-1 and a first upper S/D region 108U-1 stacked thereon with an interlayer insulating layer 109 (which may include a liner insulating layer 109L and a nonconformal insulating layer 109N) therebetween. The first lower S/D region 108L-1 has a first conductivity type (e.g., n-type), and the first upper S/D region 108U-1 has a second conductivity type (e.g., p-type) that is opposite to the first conductivity type. The structures 100a-100d further include a second stacked transistor structure 102-2 including a second upper S/D region 108U-2 stacked on the first lower S/D region 108L-1. The second upper S/D region 108U-2 has the second conductivity type (e.g., p-type). A first contact 110-1 may be connected to the first upper S/D region 108U-1, and a second contact 112 may be connected to the first lower S/D region 108L-1. A third contact 110-2 may be connected to the second upper S/D region 108U-2. The contacts 110-1, 110-2, and 112 extend through an additional interlayer insulating layer 111 (which may include a liner insulating layer 111L and a nonconformal insulating layer 111N) to contact the first upper S/D region 108U-1, the second upper S/D region 108U-2, and the first lower S/D region 108L-1, respectively. Frontside contacts 124 may penetrate the additional interlayer insulating layer 111 to contact the contacts 110-1, 110-2, and 112.

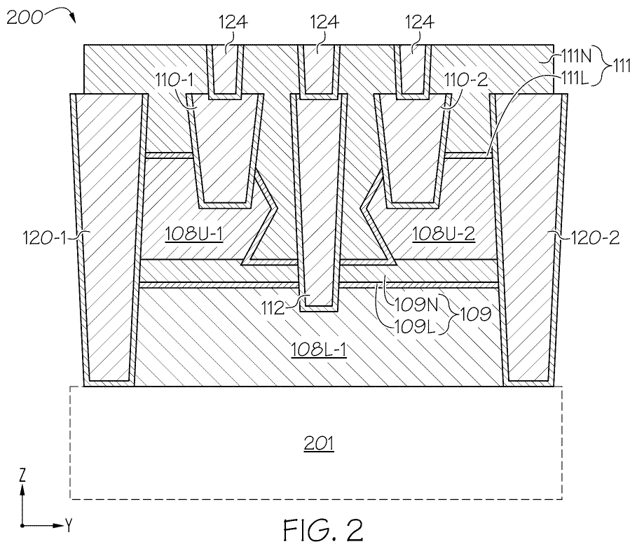

The substrate 101 may include a semiconductor material, such as a group IV semiconductor, a group III-V compound semiconductor, or a group II-VI compound semiconductor. For example, the group IV semiconductor may include silicon (Si), germanium (Ge), or silicon-germanium (SiGe). In some embodiments, the substrate 101 may be a bulk substrate (e.g., a silicon wafer), a semiconductor on insulator (SOI) substrate, an insulating layer (e.g., a monolithic insulating layer), a bulkless substrate (e.g., the 3D transistor structure 200 of FIG. 2), or the like. That is, the substrate 101 may include semiconductor material(s), for example, Si, Ge, SiGe, GaP, GaAs, SiC, SiGeC and/or InP and/or may include insulating material(s), for example, silicon oxide, silicon oxynitride, silicon nitride, silicon carbonitride and/or a low-k material. Herein, the low-k material may be a material having a dielectric constant lower than that of silicon oxide. The low-k material may include, for example, SiCOH, fluorine-doped silicon oxide, organosilicate glass, carbon-doped oxide, porous silicon dioxide, porous organosilicate glass, spin-on organic polymeric dielectrics and/or spin-on silicon based polymeric dielectric. Active regions may be defined by device isolation layers 114 on the substrate 101.

As shown in FIGS. 1A-1D, the 3D transistor structures 100a-100d further include one or more shared contacts 120-1, 120-2 (collectively 120) that respectively connect the upper S/D regions 108U to the lower S/D region(s) 108L. In particular, the 3D transistor structures 100a-100d further include a first shared contact 120-1 connecting the first upper S/D region 108U-1 to the first lower S/D region 108L-1, and a second shared contact 120-2 connecting the second upper S/D region 108U-2 to the first lower S/D region 108L-1. For example, the shared contacts 120-1, 120-2 penetrate the upper S/D regions 108U-1, 108U-2 to contact the first lower S/D region 108L-1. Upper surfaces of the shared contacts 120 may be substantially coplanar with upper surfaces of the first contact 110-1, the second contact 112, and/or the third contact 110-2 in some embodiments.

In some embodiments as shown in FIG. 1A, the shared contacts 120-1, 120-2 may be formed of a metal material (for example, cobalt (Co), tungsten (W), ruthenium (Ru), and/or molybdenum (Mo)) that connects the upper S/D regions 108U-1, 108U-2 to the first lower S/D region 108L-1. The shared contacts 120-1 and 120-2 of the 3D transistor structure 100a thereby provide semiconductor-metal-semiconductor (SMS) junctions between the first upper S/D region 108U-1 and the first lower S/D region 108L-1, and between the second upper S/D region 108U-2 and the first lower S/D region 108L-1. The SMS junctions may each include a P-type region 108U-1 or 108U-2, an N-type region 108U-1, and a metal region 120-1 or 120-2 forming a Schottky barrier therebetween. The shared contacts 120-1, 120-2 may be formed after one or more annealing or other high-temperature processes, such that the shared contacts 120-1, 120-2 are free of silicides of the metal material.

In some embodiments as shown in FIG. 1B, the shared contacts 120-1′, 120-2′ (collectively 120′) may be formed of an undoped (i.e., not intentionally doped) semiconductor material (such as undoped polysilicon) that connects the upper S/D regions 108U-1, 108U-2 to the first lower S/D region 108L-1. In some embodiments as shown in FIG. 1C, the shared contacts 120-1″, 120-2″ (collectively 120″) may be formed of a doped semiconductor material (such as doped polysilicon) that connects the upper S/D regions 108U-1, 108U-2 to the first lower S/D region 108L-1. The shared contacts 120′ and 120″ of the 3D transistor structures 100b and 100c thereby provide PIN junctions between the first upper S/D region 108U-1 and the first lower S/D region 108L-1, and between the second upper S/D region 108U-2 and the first lower S/D region 108L-1. The upper S/D region 108U, the shared semiconductor contacts 120′, 120″, and the lower S/D region 108L provide a 3D transistor structure that functions as a PIN diode. The PIN junctions each include a P-type region 108U-1 or 108U-2, an N-type region 108L-1, and a semiconductor region 120′ or 120″ providing a higher-resistance region between the P-type 108U-1 or 108U-2 and N-type 108L-1 regions.

In some embodiments as shown in FIG. 1D, the 3D transistor structure 100d may include multiple stacked transistor structures 102 that are adjacent one another (e.g., in the Y-direction), where multiple upper S/D regions 108U of the adjacent transistor structures 102 are electrically connected to one another, and multiple lower S/D regions 108L of the adjacent transistor structures 102 are electrically connected to one another. The shared contacts 120-1, 120-2 may connect one or more of the upper S/D regions 108U to one or more of the lower S/D regions 108L, thereby providing SMS junctions therebetween (where the shared contacts 120 are metal) or PIN junctions therebetween (where the shared contacts 120 are a doped or undoped semiconductor material). One of the upper S/D regions 108U (and/or channel structures may be removed or omitted such that the base contact 112 may be provided on one of the lower S/D regions 108U.

FIGS. 1A-1D illustrate integration of bipolar junction transistor (BJT) structures into the example 3D transistor structures 100a-100d by connecting upper source/drain (S/D) regions 108U-1 and 108U-2 of adjacent first and second transistor structures to one or more lower S/D regions 108L-1 by respective shared contacts 120-1 and 120-2. A first contact 110-1, a second contact 112, and a third contact 110-2 provide emitter, base, and collector contacts, respectively, of the bipolar junction transistors. That is, a first collector/emitter contact 110-1 is connected to the first upper S/D region 108U-1, a second collector/emitter contact 110-2 is connected to the second upper S/D region 108U-2, and a base contact 112 connected to the at least one lower S/D region 108L to provide a 3D transistor structure that functions as a BJT.

However, it will be understood that, in some embodiments, each of the S/D regions 108U or 108L may include a respective contact 110 or 112 thereon, to provide integrated diode structures where the first contact 110 provides anode contact, and the second contact 112 provides a cathode contact of the diode structure. In some embodiments, the shared contact 120 is formed of a metal, and the first contact 110 and the second contact 112 provide anode and cathode contacts, respectively, of a semiconductor-metal-semiconductor diode. That is, the upper S/D region 108U of the second conductivity type, the shared contact 120, and the lower S/D region 108U of the first conductivity type provide a 3D transistor structure that functions as a semiconductor-metal-semiconductor (SMS) diode. In some embodiments, the shared contact 120 is formed of a semiconductor material, and the first contact 110 and second contact 112 provide anode and cathode contacts, respectively, of a PIN diode. That is, the upper S/D region 108U of the second conductivity type, the shared contact 120, and the lower S/D region 108U of the first conductivity type provide a 3D transistor structure that functions as a PIN diode. In other words, although illustrated herein primarily with reference to integration of BJT structures into example 3D transistor structures 100 a-100d, it will be understood that the constituent SMS or PIN diode structures may be alternatively implemented.

FIG. 2 is a schematic cross-sectional view illustrating an example 3D transistor structure 200 including integrated diode structures with frontside contacts and freed of the bulk substrate according to some embodiments of the present disclosure. As shown in FIG. 2, a 3D transistor structure 200 includes at least one lower S/D region 108L-1 of a first conductivity type, and upper S/D regions 108U of a second conductivity type opposite to the first conductivity type stacked on the at least one lower S/D region 108L-1. The upper S/D regions 108U include a first upper S/D region 108U-1 and a second upper S/D region 108U-2. A first contact 110-1 may be connected to the first upper S/D region 108U-1, a second contact 112 may be connected to the lower S/D region 108L-1, and a third contact 110-2 may be connected to the second upper S/D region 108U-2. Frontside contacts 124 may penetrate the additional interlayer insulating layer 111 to contact the contacts 110-1, 110-2, and 112. A first shared contact 120-1 connects the first upper S/D region 108U-1 to the at least one lower S/D region 108L-1, and a second shared contact 120-2 connects the second upper S/D region 108U-2 to the at least one lower S/D region 108L-1. The shared contacts 120-1, 120-2 (collectively 120) may be formed of metal or semiconductor materials, to provide SMS or PIN diode structures, respectively, or BJTs including the diode structures.

The 3D transistor structure 200 of FIG. 2 may thus be similar to the 3D transistor structures 100a-100c of FIGS. 1A-1C, and as such, repeated descriptions of similar elements are omitted for brevity. However, in contrast to the 3D transistor structures 100 a-100c of FIGS. 1A-1C, the substrate 101 is omitted in the 3D transistor structure 200, such that the structure 200 is free of the underlying bulk substrate (i.e., a “bulkless” implementation 201). Also, while illustrated as having shared contacts 120 formed of metal materials similar to the structure 100a of FIG. 1A, it will be understood that the shared contacts 120 in FIG. 2 may alternatively be formed of semiconductor materials, which may be undoped (similar to the structure 100b of FIG. 1B) or doped (similar to the structure 100c of FIG. 1C).

FIG. 3 is a schematic cross-sectional view illustrating an example 3D transistor structure 300 including integrated diode structures with frontside contacts and a backside contact through the bulk substrate according to some embodiments of the present disclosure. As shown in FIG. 3, a 3D transistor structure 300 includes at least one lower S/D region 108L-1 of a first conductivity type, and upper S/D regions 108U of a second conductivity type opposite to the first conductivity type stacked on the at least one lower S/D region 108L-1. The upper S/D regions 108U include a first upper S/D region 108U-1 and a second upper S/D region 108U-2. A first contact 110-1 may be connected to the first upper S/D region 108U-1, a second contact 112 may be connected to the lower S/D region 108L-1, and a third contact 110-2 may be connected to the second upper S/D region 108U-2. A first shared contact 120-1 connects the first upper S/D region 108U-1 to the at least one lower S/D region 108L-1, and a second shared contact 120-2 connects the second upper S/D region 108U-2 to the at least one lower S/D region 108L-1. The shared contacts 120-1, 120-2 (collectively 120) may be formed of metal or semiconductor materials, to provide SMS or PIN diode structures, respectively, or BJTs including the diode structures. The structure 300 further includes a bulk semiconductor substrate 101 having the first lower S/D region 108L-1 thereon between the substrate 101 and the first upper S/D region 108U-1.

The 3D transistor structure 300 of FIG. 3 may thus be similar to the 3D transistor structures 100a-100c of FIGS. 1A-1C, and as such, repeated descriptions of similar elements are omitted for brevity. However, in contrast to the 3D transistor structures 100a-100c of FIGS. 1A-1C, the second contact 112 penetrates the bulk substrate 101 to contact the first lower S/D region 108L-1 in the structure 300 of FIG. 3 (also referred to herein as a backside contact). Frontside contacts 124 may penetrate the additional interlayer insulating layer 111 to contact the first and third contacts 110-1 and 110-2, while one or more backside contacts 126 may contact the second contact 112. In some embodiments, the second contact 112 may electrically connect the SMS or PIN diode structures (or BJTs including the diode structures) to a backside power distribution network (BSPDN).

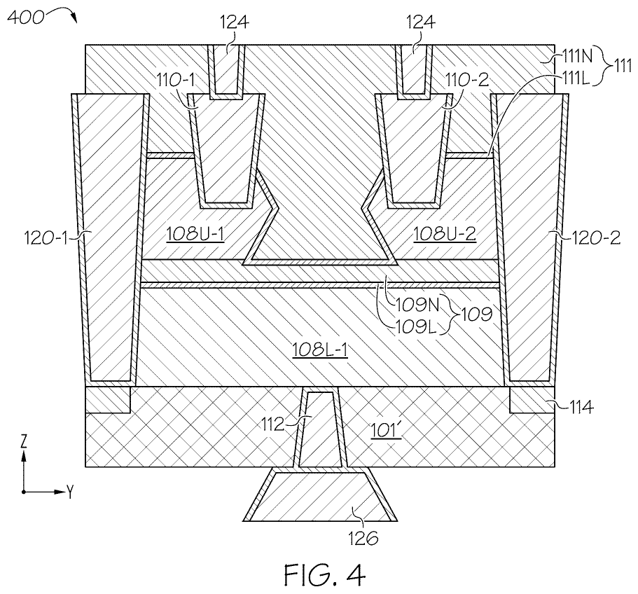

FIG. 4 is a schematic cross-sectional view illustrating an example 3D transistor structure 400 including integrated diode structures with frontside contacts and a backside contact through an insulating substrate according to some embodiments of the present disclosure. As shown in FIG. 4, a 3D transistor structure 400 includes at least one lower S/D region 108L-1 of a first conductivity type, and upper S/D regions 108U of a second conductivity type opposite to the first conductivity type stacked on the at least one lower S/D region 108L-1. The upper S/D regions 108U include a first upper S/D region 108U-1 and a second upper S/D region 108U-2. A first contact 110-1 may be connected to the first upper S/D region 108U-1, a second contact 112 may be connected to the lower S/D region 108L-1, and a third contact 110-2 may be connected to the second upper S/D region 108U-2. A first shared contact 120-1 connects the first upper S/D region 108U-1 to the at least one lower S/D region 108L-1, and a second shared contact 120-2 connects the second upper S/D region 108U-2 to the at least one lower S/D region 108L-1. The shared contacts 120-1, 120-2 (collectively 120) may be formed of metal or semiconductor materials, to provide SMS or PIN diode structures, respectively, or BJTs including the diode structures.

The 3D transistor structure 400 of FIG. 4 may thus be similar to the 3D transistor structures 100a-100c of FIGS. 1A-1C, and as such, repeated descriptions of similar elements are omitted for brevity. However, in contrast to the 3D transistor structures 100a-100c of FIGS. 1A-1C, the bulk substrate 101 is removed, and the 3D transistor structure 400 further includes an insulating substrate 101′. The second contact 112 is a backside contact that penetrates the insulating substrate 101′ to contact the first lower S/D region 108L-1 in the structure 400 of FIG. 4. Frontside contacts 124 may penetrate the additional interlayer insulating layer 111 to contact the first and third contacts 110-1 and 110-2, while one or more backside contacts 126 may contact the second contact 112. In some embodiments, the second contact 112 may electrically connect the SMS or PIN diode structures (or BJTs including the diode structures) to a BSPDN.

That is, the 3D transistor structures 300 and 400 of FIGS. 3 and 4 include bulk substrates 101 and insulating substrates 101′, respectively, where the base contact 112 penetrates the substrate 101 or 101′ to contact at least one lower S/D region 108L. By providing the diode structures on (rather than in) the underlying substrate, embodiments of the present disclosure may integrate diode structures and/or BJT structures into a 3D transistor structure even when the underlying substrate is thinned or removed to provide a BSPDN structure thereon. Also, while illustrated as having shared contacts 120 formed of metal materials similar to the structure 100a of FIG. 1A, it will be understood that the shared contacts 120 in FIGS. 3 and 4 may alternatively be formed of semiconductor materials, which may be undoped (similar to the structure 100b of FIG. 1B) or doped (similar to the structure 100c of FIG. 1C).

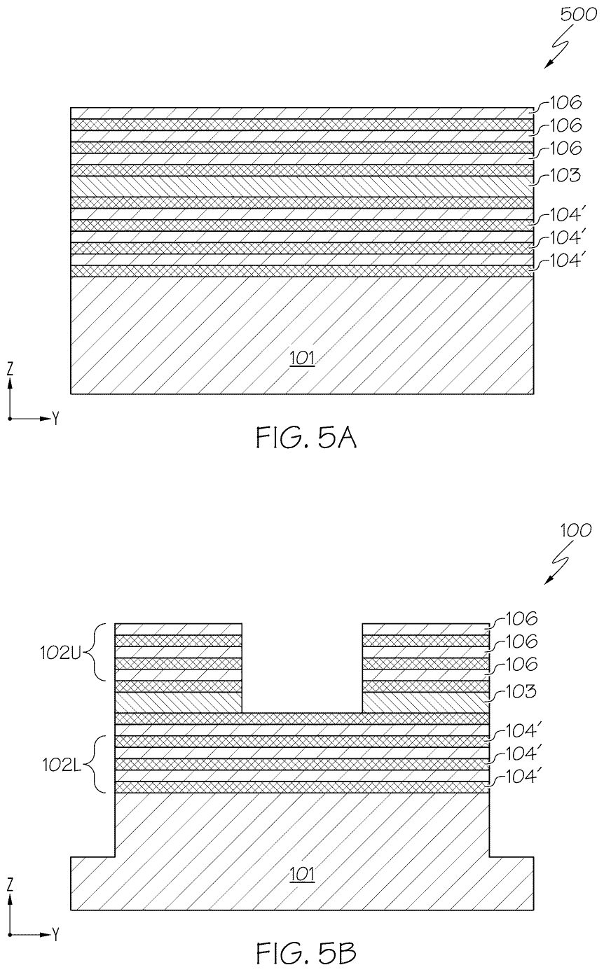

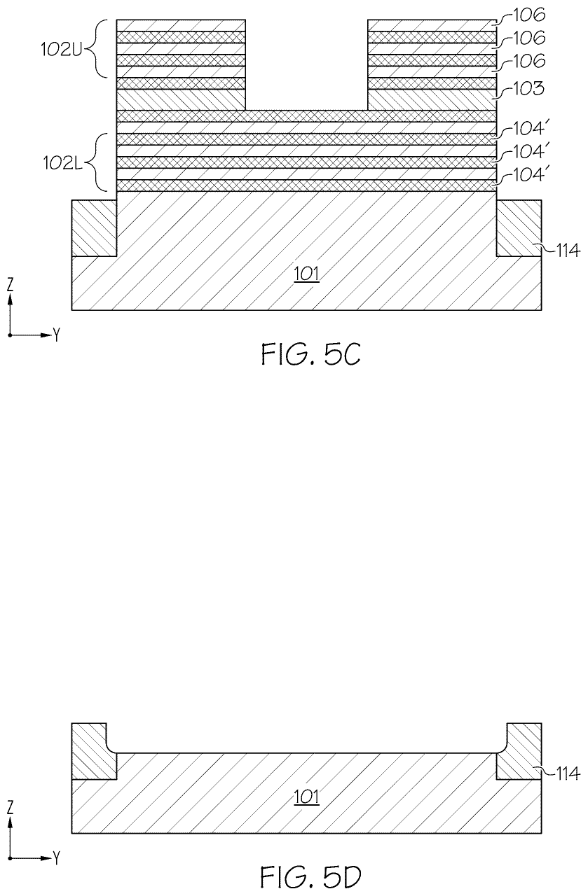

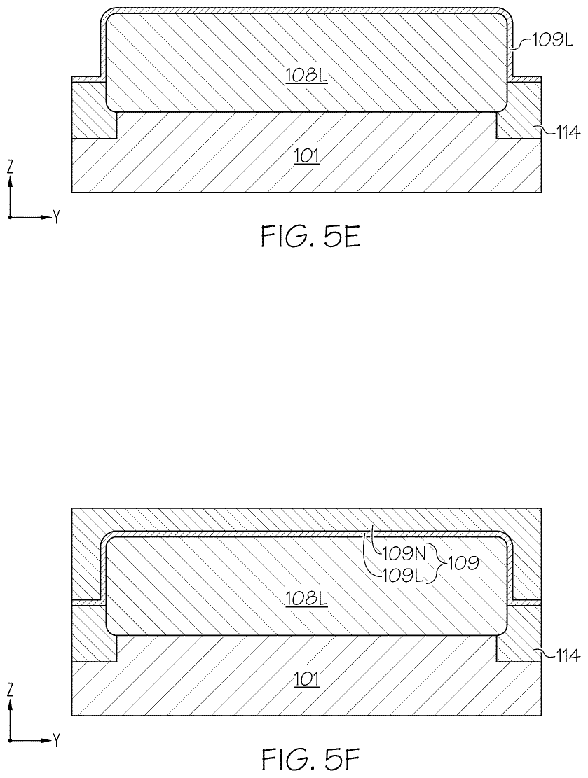

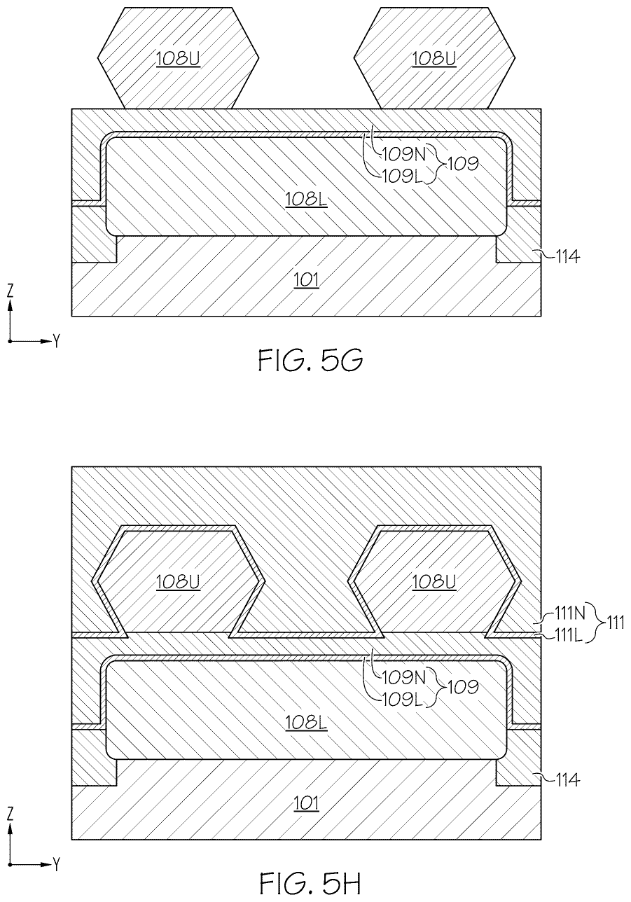

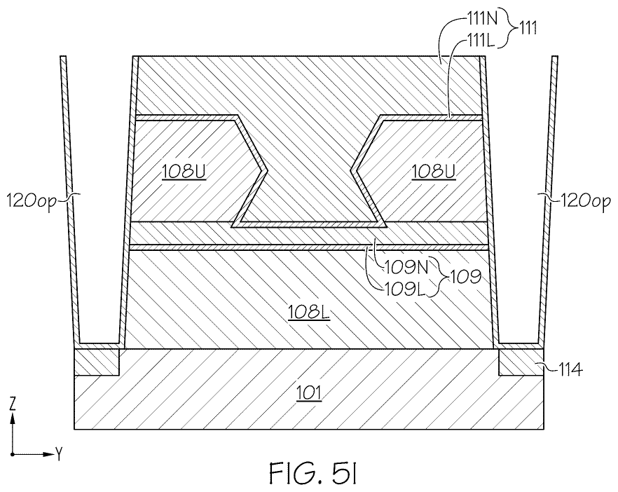

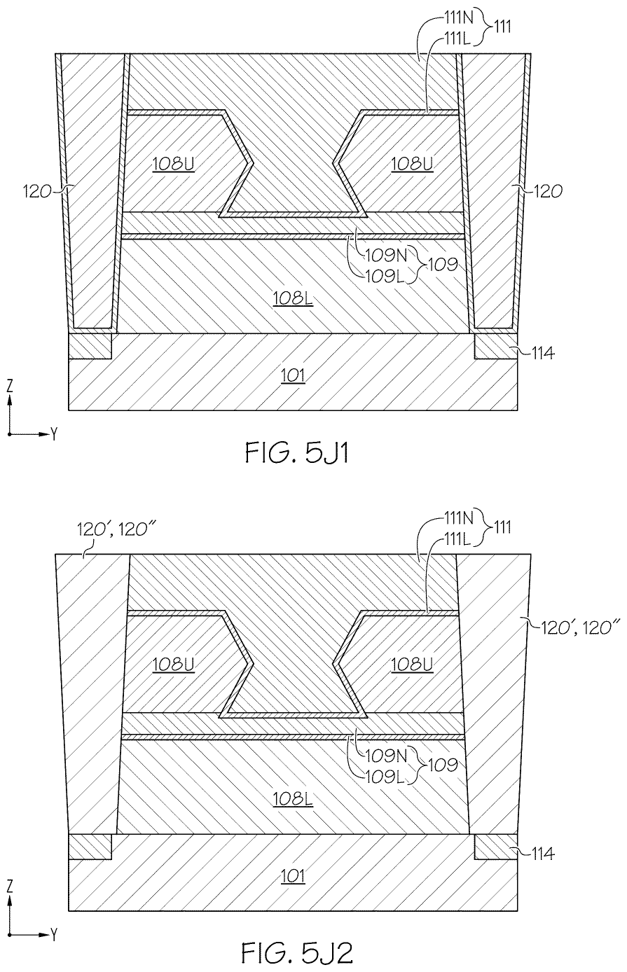

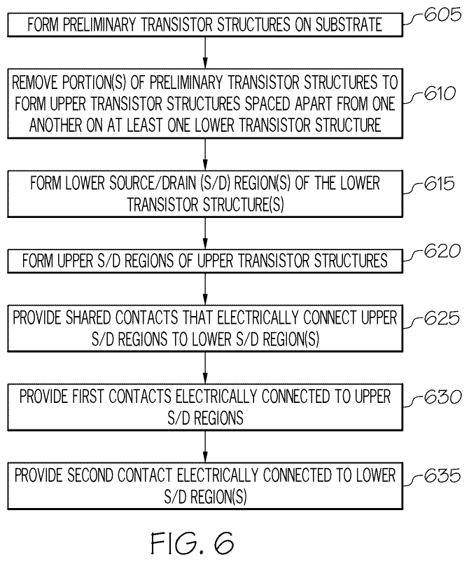

FIGS. 5A, 5B, 5C, 5D, 5E, 5F, 5G, 5H, 5I, 5J1, and 5J2 are schematic cross-sectional views illustrating methods of fabricating 3D transistor structures including integrated diode structures according to some embodiments of the present disclosure. FIGS. 5A to 5C are taken along line Y-Y of FIG. 7, while FIGS. 5D to 5J2 are taken along line Y′-Y′ of FIG. 7. FIG. 6 is a flowchart illustrating methods of fabricating a 3D transistor structure including integrated diode structures according to some embodiments of the present disclosure.

Referring now to FIG. 5A and FIG. 6, a method of fabricating a 3D transistor structure includes forming preliminary transistor structures 500 on a substrate 101 (block 605). The preliminary transistor structures include a plurality of channel layers 106 and gate sacrificial layers 104′ that are alternatingly stacked on the substrate 101. A sacrificial middle layer 103 may be provided between respective stacks of the channel layers 106 and gate sacrificial layers 104′.

As shown in FIGS. 5B and 6, portion(s) of the preliminary transistor structures 500 are removed to form 3D transistor structures 100. The 3D transistor structures 100 may include upper transistor structures 102U that are spaced apart from one another (e.g., in the Y-direction) on one or more lower transistor structures 102L (block 610). Each of the upper transistor structures 102U and the lower transistor structures 102L may include some features of stacked FET structures, but may or may not function or be operable as field effect transistors.

As shown in FIG. 5C, a device isolation layer 114 is formed on the substrate 101, for example, to form shallow trench isolation (STI) regions. The STI regions may bound or define the active regions of respective transistor structures and/or diode structures described herein, e.g., as shown in the Y-direction. FIG. 5D shows a cross-section along line Y′-Y′ (which, as shown in FIG. 7, is spaced apart from the cross-sectional view of FIG. 5C in the X-direction), illustrating bounds of the upper transistor structures 102U and the lower transistor structures 102L in the X-direction.

As shown in FIG. 5E and FIG. 6, one or more lower S/D regions 108L of the at least one lower transistor structure 102U are formed (block 615). The lower S/D regions 108L have a first conductivity type (e.g., n-type). For example, the lower S/D region(s) 108L may be formed as a single or unitary epitaxial region that is formed (i.e., by epitaxial growth) at side or end surfaces of the channel layers 106 of the lower transistor structure(s) 102-1. In some embodiments, the lower S/D region(s) 108L may be formed as a unitary implanted region that is formed (i.e., by ion implantation) at side surfaces of the channel layers 106 of the lower transistor structure(s) 102U.

As shown in FIGS. 5E and 5F, one or more interlayer insulating layers 109 are formed on the lower S/D regions 108L. For example, the interlayer insulating layers 109 may include a liner insulating layer 109L that conformally extends along an upper surface and side surfaces of the lower S/D region(s) 108L, and a nonconformal insulating layer 109N on the liner insulating layer.

As shown in FIGS. 5G and 6, upper S/D regions 108U of the upper transistor structures 102U are formed on the one or more lower S/D regions 108L (block 620). The upper S/D regions 108U have a second conductivity type that is opposite the first conductivity type. For example, the upper S/D region(s) 108U may be formed as respective epitaxial regions (i.e., formed by epitaxial growth) at side surfaces of the channel layers 106 of the upper transistor structure(s) 102U. In some embodiments, the upper S/D region(s) 108U may be formed as respective implanted regions (i.e., formed by ion implantation) at side surfaces of the channel layers 106 of the upper transistor structure(s) 102U.

As shown in FIG. 5H, additional interlayer insulating layers 111 are formed on the upper S/D regions 108U. For example, the additional interlayer insulating layers 111 may include a liner insulating layer 111L that conformally extends along an upper surface and side surfaces of the upper S/D region(s) 108U, and a nonconformal insulating layer 111N on the liner insulating layer.

As shown in FIGS. 5I, 5J1, 5J2, and FIG. 6, shared contacts 120 are formed to connect the upper S/D regions 108U to the one or more lower S/D regions 108L, respectively (block 625). In particular, as shown in FIG. 5I, contact openings 120op are formed to penetrate the upper S/D regions 108U and the interlayer insulating layer 109. As shown in FIG. 5J1 and 5J2, the shared contacts 120 are provided in the contact openings 120op. In some embodiments, as shown in FIG. 5J1, the shared contacts 120 are formed by providing one or more metal layers in the contact openings 120op. The shared contacts 120 may be formed after one or more annealing or other high-temperature processes, such that the shared contacts 120 are free of silicides of the metal layers. In some embodiments, as shown in FIG. 5J2, the shared contacts 120′, 120″ are formed by providing a one or more semiconductor layers in the contact openings 120op. The semiconductor layer(s) may be undoped (intrinsic) silicon (as shown in FIG. 5J2 and FIG. 1B), or may be doped (e.g., with P, N, As, Ga, etc.) silicon (as shown in FIG. 1C).

As shown in FIGS. 1A-1C, FIG. 2, and FIG. 6, the method further includes forming first contacts 110-1, 110-2 on the upper S/D regions 108U, respectively, (block 630), and forming a second contact 112 on the one or more lower S/D regions 108L (block 635). For example, forming the first contacts 110-1, 110-2 and the second contact 112 includes forming openings in the additional interlayer insulating layers 111 that expose the upper S/D regions 108U and the lower S/D regions 108L, respectively, and forming the first contacts 110-1, 110-2 and the second contact 112 in the openings. In some embodiments, upper surfaces of the shared contacts 120 may be substantially coplanar with upper surfaces of the first contacts 110-1, 110-2 and the second contact 112.

Alternatively, the second contact 112 may be formed as a backside contact (e.g., for a BSPDN), as shown in FIGS. 3 and 4. For example, as shown in FIG. 3 and FIG. 6, forming the second contact 112 (block 635) may include forming an opening in the substrate 101 that exposes the lower S/D region(s) 108L, and forming the second contact 112 in the opening. As another example, as shown in FIG. 4 and FIG. 6, the semiconductor substrate 101 may be removed after forming the first 110-1, 110-2, an insulating substrate 101′ may be formed on the lower S/D region(s) 108L, an opening may be formed in the insulating substrate 101′ that exposes the lower S/D region(s) 108L, and the second contact 112 may be formed in the opening.

According to embodiments described herein, 3D transistor structures including integrated diode structures with shared contacts may be formed on a bulk substrate (which may be removed or replaced with an insulating substrate in some embodiments). The transistor may include base, collector, and emitter regions that are on the first side of the bulk substrate, and shared contacts (metal or semiconductor) that are on the first side of the bulk substrate and electrically connect respective opposite conductivity type source/drain regions to thereby form SMS or PIN diode structures. Elements (e.g., SMS or PIN junctions) of the diode structures may thereby be formed concurrently with elements (e.g., channel layers and/or source/drain regions) of stacked field effect transistors using many of the same fabrication processes, and respective contacts may be formed on the first side and/or on the second side of the bulk substrate to provide a BJT including collector/emitter and base terminals (or a diode including anode and cathode terminals), even when the underlying substrate is removed or thinned to provide a backside power distribution network structure. That is, one or more source/drain regions of a 3DSFET structure may form or may otherwise implement the emitter, base, and collector regions of a BJT (or the P-N junctions of a diode).

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein. For example, as noted herein, an “insulating” layer or liner may include dielectric materials (which may be polarizable by an applied electric field).

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of stated features, steps, operations, elements and/or components, but do not preclude the presence or addition of one or more other features, steps, operations, elements, components and/or groups thereof.

It will be understood that, although the terms “first,” “second,” etc. are used throughout this specification to describe various elements, these elements should not be limited by these terms. These terms are only used to distinguish one element from another. For example, a first element could be termed a second element, and, similarly, a second element could be termed a first element, without departing from the scope of the present disclosure. The term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Elements that are “connected” as described herein may be physically and/or electrically connected.

Spatially relative terms such as “below” or “above” or “upper” or “lower” or “top” or “bottom” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Many different forms and embodiments are possible without deviating from the teachings of this disclosure. Accordingly, the disclosure should not be construed as limited to the example embodiments set forth herein. As such, it will be understood by those of ordinary skill in the art that various changes in form and details may be made therein without departing from the spirit and scope as defined herein.

Embodiments of the invention are also described with reference to a fabrication operations and flowchart diagrams. It will be appreciated that the steps shown in the fabrication operations and flowchart diagrams need not be performed in the order shown.

The above-disclosed subject matter is to be considered illustrative, and not restrictive, and the appended claims are intended to cover all such modifications, enhancements, and other embodiments, which fall within the scope of the disclosure. Thus, to the maximum extent allowed by law, the scope is to be determined by the broadest permissible interpretation of the following claims and their equivalents, and shall not be restricted or limited by the foregoing detailed description.

1. A three-dimensional (3D) transistor structure, comprising:
a first stacked transistor structure comprising a first lower source/drain (S/D) region and a first upper S/D region stacked thereon with an insulating layer therebetween, wherein the first lower S/D region has a first conductivity type, and the first upper S/D region has a second conductivity type that is opposite to the first conductivity type; and
a first contact connected to the first upper S/D region;
a second contact connected to the first lower S/D region; and
a shared contact connecting the first upper S/D region to the first lower S/D region.

2. The 3D transistor structure of claim 1, wherein the shared contact penetrates the first upper S/D region to contact the first lower S/D region.

3. The 3D transistor structure of claim 1, wherein the shared contact comprises a metal, and wherein the first and second contacts comprise anode and cathode contacts of a semiconductor-metal-semiconductor (SMS) diode.

4. The 3D transistor structure of claim 3, wherein the shared contact is free of a silicide of the metal.

5. The 3D transistor structure of claim 1, wherein the shared contact comprises a semiconductor, wherein the first and second contacts comprise anode and cathode contacts of a PIN diode.

6. The 3D transistor structure of claim 5, wherein the semiconductor comprises undoped silicon.

7. The 3D transistor structure of claim 5, wherein the semiconductor comprises doped silicon.

8. The 3D transistor structure of claim 1, wherein the shared contact is a first shared contact, and further comprising:
a second stacked transistor structure comprising a second upper S/D region stacked on the first lower S/D region, wherein the second upper S/D region has the second conductivity type;
a second shared contact connecting the second upper S/D region to the first lower S/D region; and
a third contact connected to the second upper S/D region,
wherein the first, second, and third contacts comprise emitter, base, and collector contacts, respectively, of a bipolar junction transistor.

9. The 3D transistor structure of claim 1, further comprising:
a substrate having the first lower S/D region thereon between the substrate and the first upper S/D region, wherein the second contact penetrates the substrate to contact the first lower S/D region.

10. The 3D transistor structure of claim 9, wherein the substrate comprises a bulk semiconductor substrate or an insulating substrate.

11. The 3D transistor structure of claim 1, wherein an upper surface of the shared contact is substantially coplanar with an upper surface of the first contact and/or the second contact.

12. A three-dimensional (3D) transistor structure, comprising:
at least one lower source/drain (S/D) region of a first conductivity type;
upper S/D regions of a second conductivity type opposite to the first conductivity type stacked on the at least one lower S/D region, the upper S/D regions comprising a first upper S/D region and a second upper S/D region;
a first shared contact connecting the first upper S/D region to the at least one lower S/D region;
a second shared contact connecting the second upper S/D region to the at least one lower S/D region;
a first collector/emitter contact connected to the first upper S/D region;
a second collector/emitter contact connected to the second upper S/D region; and
a base contact connected to the at least one lower S/D region.

13. The 3D transistor structure of claim 12, wherein the first and second shared contacts penetrate the first upper S/D region and the second upper S/D region, respectively, to contact the at least one lower S/D region.

14. The 3D transistor structure of claim 12, wherein the first and second shared contacts comprise metal.

15. The 3D transistor structure of claim 12, wherein the first and second shared contacts comprise a doped or undoped semiconductor.

16. The 3D transistor structure of claim 12, further comprising:
a substrate having the at least one lower S/D region thereon between the substrate and the upper S/D regions, wherein the base contact penetrates the substrate to contact the at least one lower S/D region.

17. A method of fabricating a three-dimensional (3D) transistor structure, the method comprising:
forming preliminary transistor structures on a substrate;
removing a portion of the preliminary transistor structures to form upper transistor structures that are spaced apart from one another on one or more lower transistor structures;
forming one or more lower source/drain (S/D) regions of the at least one lower transistor structure, the one or more lower S/D regions having a first conductivity type;
forming upper S/D regions of the upper transistor structures on the one or more lower S/D regions with an interlayer insulating layer therebetween, the upper S/D regions having a second conductivity type that is opposite the first conductivity type; and
forming shared contacts that connect the upper S/D regions to the one or more lower S/D regions.

18. The method of claim 17, wherein forming the shared contacts comprises:
forming contact openings that penetrate the upper S/D regions and the interlayer insulating layer; and
forming the shared contacts in the contact openings.

19. The method of claim 18, wherein forming the shared contacts comprises forming a metal in the contact openings.

20. The method of claim 18, wherein forming the shared contacts comprises forming a semiconductor in the contact openings.

21-27. (canceled)
